(19) United States
(12) Patent Application Publication
(10) Pub. No.: US 2022/0236694 A1
(43) Pub. Date: Jul. 28, 2022

(54) Electronic Watch And Method For Controlling Electronic Watch

(71) Applicant: Seiko Epson Corporation, Tokyo (JP)

(72) Inventor: Norimitsu BABA, Shiojiri (JP)

(21) Appl. No.: 17/584,446

(22) Filed: Jan. 26, 2022

(30) Foreign Application Priority Data
Jan. 27, 2021 (JP) 2021-011162

(51) Int. Cl. G04C 10/04; G04B 19/04

(52) U.S. Cl. CPC G04C 10/04; G04C 3/14; G04B 19/04

(57) ABSTRACT

An electronic watch includes a plurality of hands configured to display time, a power generator, an power storage unit configured to store power generated by the power generator, an indicator hand configured to display a power storage amount in the power storage unit in a plurality of stages, a controller configured to perform control switching between a normal time display mode in which time is displayed by the hand and a power save mode in which at least one of the hands is stopped. The controller detects the power storage amount and updates display of the based on the power storage amount by the indicator hand during the power save mode.

The present application is based on, and claims priority from JP Application Serial Number 2021-011162, filed Jan. 27, 2021, the disclosure of which is hereby incorporated by reference herein in its entirety.

### BACKGROUND

### 1. Technical Field

The present disclosure relates to an electronic watch and a method for controlling an electronic watch.

### 2. Related Art

JP-A-2007-263717 discloses a rechargeable electronic watch including a secondary battery that stores electrical energy from a power generation unit such as a solar cell, a voltage detection circuit that detects a voltage of the secondary battery, and a remaining capacity display unit that displays a remaining capacity of the secondary battery based on the detected voltage.

In a normal mode, the remaining capacity display unit updates display content according to the remaining capacity of the secondary battery, and in a power save mode in which a hand movement is stopped, the remaining capacity display unit stops operation of updating the display content of the remaining capacity and also returns from the power save mode to the normal mode to perform charge warning operation when detecting a voltage below a predetermined voltage that requires a user to charge.

In the rechargeable electronic watch of JP-A-2007-263717, the update operation of the display content of the remaining capacity is stopped during the power save mode, and a user of the electronic watch is unable to know the voltage of the secondary battery until the voltage of the secondary battery drops below the voltage at which the charge warning operation is performed. In particular, when a plurality of electronic watches are owned, the watches other than the watch in use transition to the power save mode while being stored at home or the like, so that the plurality of watches may be in charge warning states at the same time. If the charge warning state is left, the watch stops completely. If the watch stopped, it takes time for the user to reset the time after generating power. In order not to stop the watches in the charge warning state, it is necessary to charge (store power) the secondary battery by the power generation unit of those watches, and when the number of watches owned increases, watch management operation increase and thus inconvenient.

### SUMMARY

An electronic watch of the present disclosure includes a plurality of hands configured to display time, a power generator, a power storage unit configured to store power generated by the power generator, an indicator hand configured to display a power storage amount in the power storage unit in a plurality of stages, a controller configured to perform control switching between a normal time display mode in which time is displayed by the hand and a power save mode in which at least one of the hands is stopped, and the controller detects the power storage amount and updates display of the power storage amount by the indicator hand during the power save mode.

An electronic watch of the present disclosure includes a plurality of hands configured to display time, a power generator, a power storage unit configured to store power generated by the power generator, and a controller configured to perform control switching between a normal time display mode in which time is displayed by the hand and a power save mode with less power consumption than the normal time display mode, and when switched from the normal time display mode to the power save mode, the controller displays a power storage amount in the power storage unit in a plurality of stages by one hand of the hands.

A method for controlling an electronic watch according to the present disclosure, the electronic watch including a plurality of hands configured to display time, a power generator, a power storage unit configured to store power generated by the power generator, and an indicator hand configured to display a power storage amount in the power storage unit, the method including, when a switching condition is satisfied while performing normal time display mode, switching to a power save mode in which at least one of the hands is stopped, and while performing the power save mode, detecting the power storage amount in the power storage unit, and causing the indicator hand to display the power storage amount in a plurality of stages.

A method for controlling an electronic watch according to the present disclosure, the electronic watch including a plurality of hands configured to display time, a power generator, and a power storage unit configured to store power generated by the power generator, the method including, when a switching condition is satisfied while performing a normal time display mode in which time is displayed by the hands, switching to a power save mode with less power consumption than the normal time display mode, and while performing the power save mode, during performance of the power save mode, detecting the power storage amount in the power storage unit, and displaying the power storage amount in a plurality of stages by one hand of the hands.

### BRIEF DESCRIPTION OF THE DRAWINGS

FIG. 1 is a front view illustrating an electronic watch according to a first embodiment.

FIG. 2 is a block diagram illustrating a schematic configuration of the electronic watch according to the first embodiment.

FIG. 3 is a diagram illustrating settings for each voltage level.

FIG. 4 is a flowchart illustrating a mode switching process in a normal time display mode according to the first embodiment.

FIG. 5 is a flowchart illustrating the mode switching process in a power save mode according to the first embodiment.

FIG. 6 is a timing chart of the first embodiment.

FIG. 7 is a front view illustrating an electronic watch according to a second embodiment.

FIG. 8 is a front view illustrating an electronic watch according to a third embodiment.

FIG. 9 is a flowchart illustrating a mode switching process in a normal time display mode according to the third embodiment.

FIG. 10 is a flowchart illustrating the mode switching process in a power save mode according to the third embodiment.

FIG. 11 is a flowchart illustrating a mode switching process in a normal time display mode according to the fourth embodiment.

FIG. 12 is a flowchart illustrating the mode switching process in a power save mode according to the third embodiment.

### DESCRIPTION OF EXEMPLARY EMBODIMENTS

### First Embodiment

An electronic watch 1 according to a first embodiment of the present disclosure will be described below with reference to the drawings.

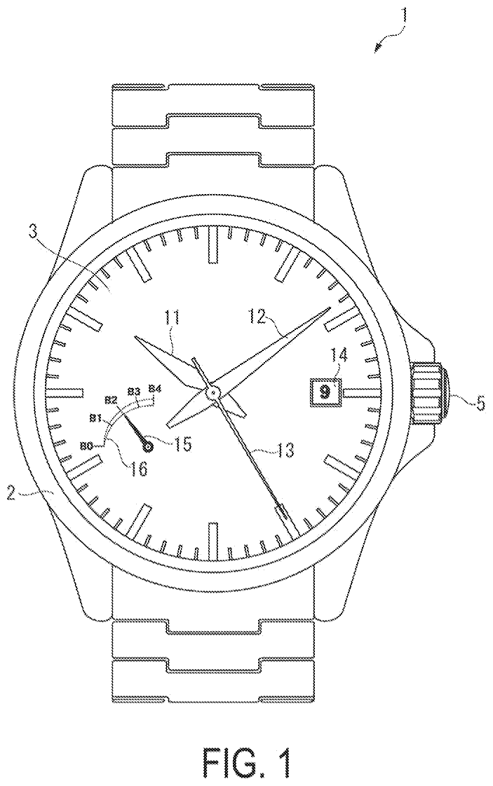

As illustrated in FIG. 1, the electronic watch 1 according to the present embodiment is a watch which is worn on a user's wrist, and includes an outer case 2, a dial 3 having a disk shape, an hour hand 11, a minute hand 12, and a seconds hand 13 which are hands, a date indicator 14, an indicator hand 15 that displays a power storage amount in a plurality of stages, and a movement (not illustrated). The hour hand 11, the minute hand 12, and the seconds hand 13 are center hands whose rotation axes are provided at a plane center position of the dial 3. The indicator hand 15 is a functional hand whose rotation axis is provided at an intermediate position side between 7 o'clock and 8 o'clock with respect to the plane center position of the dial 3.

On a side surface of the outer case 2, a crown 5 which is an operation device 21 is provided in the 3 o'clock direction with respect to the center of the dial 3. The crown 5 is an electronic type capable of outputting a pull-out position, a rotation direction, and a rotation amount using a digital signal.

The dial 3 includes a scale 16 that indicates a power storage amount instructed by the indicator hand 15 in a plurality of stages. In the present embodiment, the scale 16 includes five-stage scales of “B0, B1, B2, B3, and B4”. The scale 16 is formed in an approximately ¼ circle, the scale B0 that indicates the lowest power storage amount is arranged in the 9 o'clock direction with respect to the rotation axis of the indicator hand 15, the scale B4 that indicates the highest power storage amount is arranged in a 12 o'clock direction with respect to the rotation axis of the indicator hand 15, and the scales B1 to B3 are arranged at equal intervals between the scales B0 and B4.

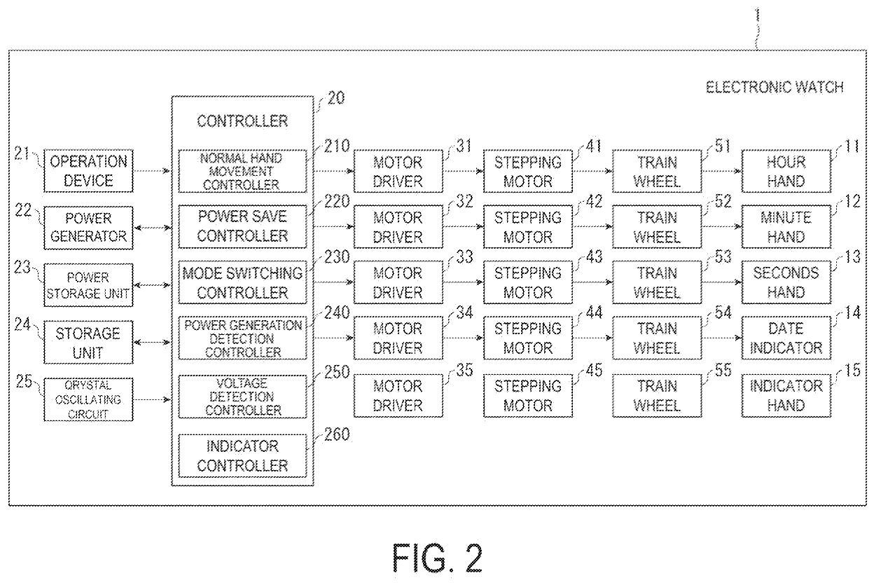

FIG. 2 is a block diagram illustrating a configuration of the electronic watch 1.

The electronic watch 1 includes a controller 20, the operation device 21, a power generator 22, a power storage unit 23, a storage unit 24, and a crystal oscillating circuit 25. Further, the electronic watch 1 includes motor drivers 31 to 35, stepping motors 41 to 45, and train wheels 51 to 55.

The operation device 21 is the crown 5, and outputs a signal corresponding to the pull-out position of the crown 5 and a signal corresponding to the rotation operation thereof to the controller 20. Therefore, the controller 20 can detect the position, the rotation direction, and the rotation amount of the crown 5 by the signal input from the operation device 21.

The power generator 22 is constituted by a solar cell, an electromagnetic induction type power generation device that rotates a power generation rotor by a rotary weight or manual winding operation to generate power using a power generation coil, and the like. Note that the power generator 22 may be an electrostatic power generation device using an electret element, a power generation device using a piezoelectric element, a thermal power generation device, or the like.

The power storage unit 23 is constituted by a secondary battery, a capacitor, or the like that stores electric energy generated by the power generator 22.

The storage unit 24 is constituted by a RAM (Random Access Memory) and a ROM (Read Only Memory), and stores a program, information necessary for executing the program, and the like.

The crystal oscillating circuit 25 generates a reference frequency signal that serves as a reference for time measurement and a clock of the controller 20. The reference frequency is 32768 Hz, and the controller 20 divides the frequency by 32768 to obtain a signal of 1 Hz, that is, 1 second.

The controller 20 is constituted by a microcomputer, a dedicated IC (Integrated Circuit), or the like, and performs control of the electronic watch 1, and implements each function by executing the program stored in the storage unit 24. The controller 20 includes a normal hand movement controller 210, a power save controller 220, a mode switching controller 230, a power generation detection controller 240, a voltage detection controller 250, and an indicator controller 260. The controller 20 keeps counting the signal of 1 second and holds the time. Then, the user can operate the operation device 21 to correct the time.

The normal hand movement controller 210 is performed in a normal time display mode, and controls the motor drivers 31 to 34 to display the time using the hour hand 11, the minute hand 12, the seconds hand 13, and the date indicator 14.

The power save controller 220 is performed in a power save mode. In the present embodiment, the power save controller 220 performs a first power save mode and a second power save mode, and gradually stops the hour hand 11, the minute hand 12, the seconds hand 13, and the date indicator 14, which are hands for displaying the time to suppress power consumption.

The first power save mode is a mode in which the seconds hand 13 is stopped and the operation of the other hour hand 11, minute hand 12, and the date indicator 14 continues. That is, the first power save mode is a mode in which the seconds hand 13, which is one of the plurality of hands that displays the time, is stopped. Note that the seconds hand 13 stops at 0 second position in order to clarify that it has stopped in the power save mode.

In the second power save mode, the hour hand 11, the minute hand 12, the seconds hand 13, and the date indicator 14 are stopped.

That is, the second power save mode is a mode in which all the plurality of hands that display the time are stopped. Note that the seconds hand 13 stops at the 0 second position as in the first power save mode. Further, the hour hand 11 and the minute hand 12 stop at the same 12 o'clock position as the seconds hand 13, but may stop at positions at the time of transitioning to the second power save mode without moving to the 12 o'clock position. Further, the date indicator 14 may stop at the time of transitioning to the second power save mode, but may move to a position where “1st” is displayed and stop, or a mark indicating the power save mode may be indicated on the date indicator 14 and the date indicator 14 may move to a position where the mark is displayed and stop.

The power generation detection controller 240 detects a power generation current and the like output from the power generator 22, and detects whether or not the power generator 22 is generating power.

The voltage detection controller 250 detects battery voltage of the power storage unit 23 constituted by the secondary battery or the like.

Since the battery voltage varies according to the amount of electric charge to be stored, the power storage unit 23 can estimate the power storage amount of the power storage unit 23 by detecting the battery voltage.

The indicator controller 260 operates the indicator hand 15 based on the battery voltage of the power storage unit 23 detected by the voltage detection controller 250 to display the amount of electric charge stored in the battery, that is, the power storage amount. In the present embodiment, the indicator controller 260 operates in both the normal time display mode and the power save mode and displays the power storage amount.

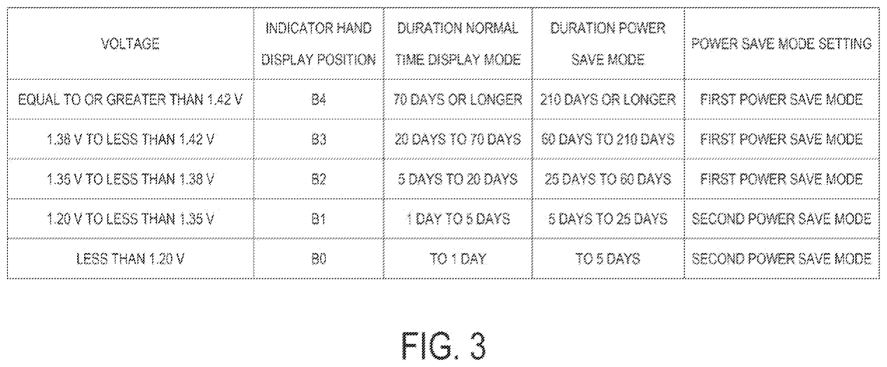

FIG. 3 illustrates the voltage of the power storage unit 23, a display position of the indicator hand 15, a duration in the normal time display mode which is the normal hand movement, a duration in the power save mode, and a kind of the power save mode to be performed. Note that, in the present embodiment, when the voltage of the power storage unit 23 becomes less than 1.0 V, the controller 20 stops and the time cannot be counted. Therefore, the duration is a time until the voltage of the power storage unit 23 drops to less than 1.0 V and the controller 20 stops.

That is, the electronic watch 1 operates according to the stored electric charge, and the duration is a time during which the electronic watch 1 can continue to operate with the current electric charge amount, and is the duration that can hold the time to be counted.

As illustrated in FIG. 3, when the voltage of the power storage unit 23 is equal to or greater than 1.42 V, the indicator controller 260 displays B4 of the scale 16 by the indicator hand 15. When the voltage of the power storage unit 23 is equal to or greater than 1.42 V, the duration in the normal time display mode is 70 days or longer, whereas the duration in the power save mode is 210 days or longer. When the voltage of the power storage unit 23 is equal to or greater than 1.42 V, the power save controller 220 performs the first power save mode.

Similarly, as illustrated in FIG. 3, when the voltage of the power storage unit 23 is from 1.38 V to less than 1.42 V, the indicator hand 15 displays B3 and the first power save mode is performed. When the voltage of the power storage unit 23 is from 1.35 V to less than 1.38 V, the indicator hand 15 displays B2 and the first power save mode is performed. When the voltage of the power storage unit 23 is from 1.20 V to less than 1.35 V, the indicator hand 15 displays B1 and the second power save mode is performed. When the voltage of the power storage unit 23 is less than 1.20 V, the indicator hand 15 displays B0 and the second power save mode is performed. Accordingly, in the present embodiment, a switching threshold value for switching between the first power save mode and the second power save mode is set to 1.35 V.

The duration of each voltage level in the normal time display mode and in the power save mode is as illustrated in FIG. 3. During the performance of the first power save mode, the seconds hand 13 is stopped and the power consumption is suppressed. Therefore, the duration is approximately three times greater than that in the normal time display mode. During the performance of the second power save mode, the hour hand 11, the minute hand 12, the seconds hand 13, and the date indicator 14 are stopped, and the power consumption is further suppressed. Therefore, the duration is approximately five times greater than that in the normal time display mode.

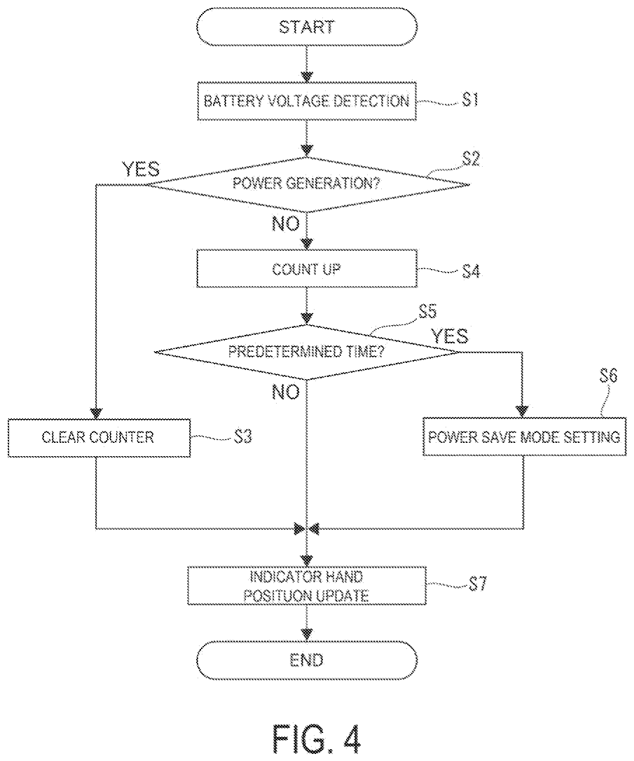

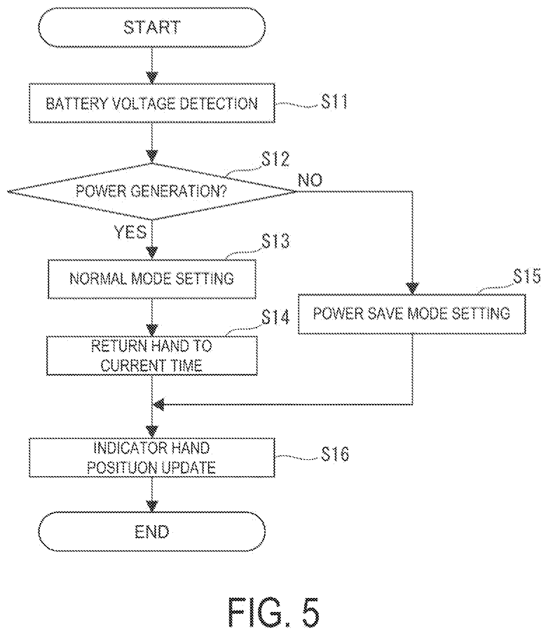

Next, a mode switching process by the mode switching controller 230 will be described with reference to flowcharts of FIGS. 4 and 5.

The mode switching controller 230 performs the process in FIG. 4 every 2 seconds in the normal time display mode. When the mode switching controller 230 performs the process of FIG. 4, the mode switching controller 230 performs a step S1 to detect the battery voltage, that is, the power storage amount, by the voltage detection controller 250. Next, the mode switching controller 230 performs a step S2, and whether or not the power generator 22 is in a power generation state is determined by the power generation detection controller 240.

When determining YES in the step S2, that is, when there is power generation, the mode switching controller 230 performs a step S3 and clears a counter provided in the storage unit 24.

On the other hand, when determining NO in the step S2, that is, when there is no power generation, the mode switching controller 230 performs a step S4 and counts up the counter.

Next, the mode switching controller 230 performs a step S5 and determines whether or not the duration of a non-power generation state has reached a predetermined time based on the counter value, that is, determines whether or not a switching condition for switching from the normal time display mode to the power save mode is satisfied. That is, the counter is cleared when the power generation is detected at the time of the power generation detection of every 2 seconds, and is sequentially counted up when the non-power generation state continues. Therefore, the duration of the non-power generation state can be calculated by multiplying the counter value of the counter by 2 seconds, and it can be determined whether or not the duration of the non-power generation state is equal to or greater than the predetermined time. The predetermined time, that is, the switching condition in the step S5 is set according to the type of the electronic watch 1 and the type of the power generator 22, and is set to, for example, 3 hours, 6 hours, 12 hours, and the like. Further, in a case where the power generator 22 is a solar cell, when the predetermined time is set as short as approximately 3 hours, the switching condition to the power save mode may be satisfied even if the electronic watch 1 hidden behind the sleeve is in use. Therefore, it is desirable to set the predetermined time as long as 24 hours.

When determining YES in the step S5, the mode switching controller 230 performs a step S6 and sets the power save mode. At this time, when the battery voltage detected in the step S1 is equal to or greater than 1.35V, the first power save mode is set, and when the battery voltage detected in the step S1 is less than 1.35 V, the second power save mode is set.

Then, the mode switching controller 230 performs a step S7 after the process of the step S3 or the step S6, or after determining NO in the step S5, and updates a display position of the indicator hand 15 by the indicator controller 260, and ends the mode switching process of FIG. 4.

Therefore, the mode switching controller 230 performs the process of FIG. 4 every 2 seconds when the normal time display mode is continued, and the indicator hand 15 displays the battery voltage or the power storage amount of the power storage unit 23 in five stages of B0 to B5 every 2 seconds.

After the mode switching process, when the power save mode is set in the step S6 of FIG. 4, the controller 20 performs each power save mode, and as described above, stops at least one of the plurality of hands indicating the time.

Further, the mode switching controller 230 performs the process illustrated in FIG. 5 in the power save mode. Note that the process of FIG. 5 may be performed at intervals of 2 seconds as in the normal time display mode, but in the present embodiment, is performed at intervals longer than 2 seconds, for example, every minute or every hour.

When the mode switching controller 230 performs the process of FIG. 5, the mode switching controller 230 performs a step S11 to detect the battery voltage, that is, the power storage amount by the voltage detection controller 250. Next, the mode switching controller 230 performs a step S12, and whether or not the power generator 22 is in the power generation state is determined by the power generation detection controller 240.

When determining YES in the step S12, the mode switching controller 230 sets the normal mode, that is, the normal time display mode in a step S13, and performs a step S14 in which the hand that has stopped in the power save mode is returned to the position indicating the current time.

On the other hand, when determining NO in the step S12, the mode switching controller 230 performs a step S15 and maintains the setting of the power save mode.

Next, the mode switching controller 230 performs a step S16 after the process of the step S14 or the step S15, updates the display position of the indicator hand 15 by the indicator controller 260, and ends the mode switching process of FIG. 5.

Therefore, the detection interval for the power storage amount during the power save mode is set to be longer than the detection interval for the power storage amount during the normal time display mode.

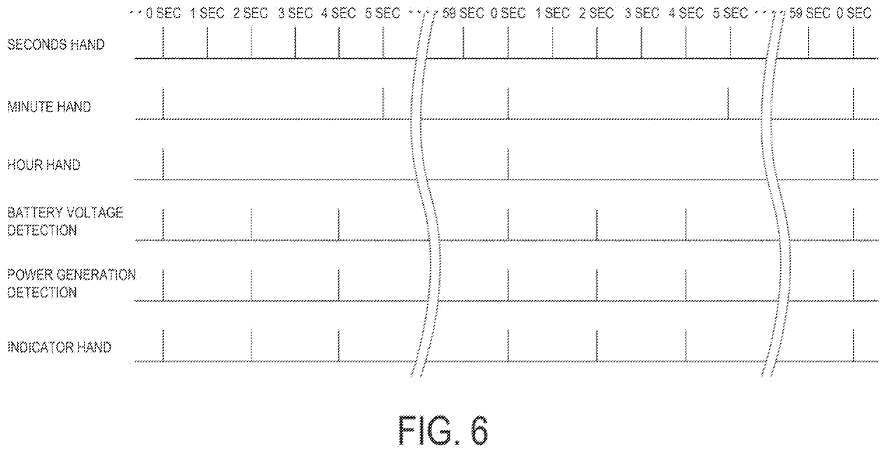

FIG. 6 is a timing chart illustrating movement timings of the hour hand 11, the minute hand 12, the seconds hand 13, and the indicator hand 15, power generation detection timings by the power generation detection controller 240, and battery voltage detection timings by the voltage detection controller 250, in the normal time display mode.

Note that the train wheel 53 of the seconds hand 13 is configured with a reduction ratio in which the seconds hand 13 makes a round when the stepping motor 43 moves 60 steps. Therefore, the seconds hand 13 is moved in 60 segments and rotates 6° per step of the stepping motor 43.

The train wheel 52 of the minute hand 12 is configured with a reduction ratio in which the minute hand 12 makes a round when the stepping motor 42 moves 720 steps. The minute hand 12 is moved in 720 segments and rotates 0.5° per step of the stepping motor 42.

The train wheel 51 of the hour hand 11 is configured with a reduction ratio in which the hour hand 11 makes a round when the stepping motor 41 moves 720 steps. The hour hand 11 is moved in 720 segments and rotates 0.5° per step of the stepping motor 41.

As illustrated in FIG. 6, the normal hand movement controller 210 moves the seconds hand 13 one step per second, moves the minute hand 12 one step per 5 seconds, and moves the hour hand 11 one step per minute. Although not illustrated in FIG. 6, the normal hand movement controller 210 operates the date indicator 14 once a day to update the date display.

Further, as described above, the voltage detection controller 250 performs the battery voltage detection every 2 seconds, the power generation detection controller 240 performs the power generation detection every 2 seconds, and the indicator controller 260 operates the indicator hand 15 every 2 seconds. Note that since the voltage of the power storage unit 23 does not vary significantly in a short period of time, the detected voltage value often does not vary even when the battery voltage is detected every 2 seconds. Therefore, the interval in which the indicator hand 15 actually moves is longer than 2 seconds. As illustrated in FIG. 3, duration of each display position (B0 to B4) of the indicator hand 15 is on a daily basis, and the operation of the indicator hand 15 for changing the display position is performed on a daily basis, which is a long interval.

As described above, since the seconds hand 13 has the shortest operation interval, power consumption can be reduced and the effect of the power save mode can be increased by stopping at least the seconds hand 13 in the power save mode.

Further, in the present embodiment, as illustrated in FIG. 6, the battery voltage detection is performed at intervals of 2 seconds, and the power generation detection is performed at the same intervals of 2 seconds. However, the battery voltage detection may be performed at such as intervals of 10 seconds, and the power generation detection may be performed at different intervals of such as 2 seconds.

### Operations and Effects of First Embodiment

According to the present embodiment, the indicator hand 15 is operated not only in the normal time display mode but also in the power save mode to display the power storage amount in the power storage unit 23, specifically, display the battery voltage at five stages of B0 to B4. Therefore, the user of the electronic watch 1 can understand the decrease in the power storage amount even in the power save mode, and can operate the power generator 22 to increase the power storage amount before the power storage amount decreases to a level at which the controller 20 stops. Thus, a user having a plurality of the electronic watches 1 can select the electronic watch 1 having a low level displayed by the indicator hands 15 from among the plurality of the electronic watches 1 that have transitioned to the power save mode to generate power preferentially, thereby preventing the controller 20 from stopping due to the voltage drop. That is, when the controller 20 stops and the time cannot be counted, the user needs to store electricity until the controller 20 operates and then reset the time, but this effort becomes unnecessary.

In the present embodiment, the detection interval of the power storage amount in the power save mode is set longer than the detection interval of the power storage amount in the normal time display mode. Therefore, in addition to power saving effect by stopping the hand, the power saving effect can be increased by reducing a frequency of the detection of the power storage amount.

In the present embodiment, since the power save mode is set when the duration of the non-power generation state is longer than the predetermined time, the user does not need to perform operation to switch to the power save mode, and the electronic watch 1 stored at home or the like can be automatically switched to the power save mode, and thus can save power effectively.

In the present embodiment, the first power save mode and the second power save mode that consumes less power are included as the power save mode. Therefore, when the power storage amount decreases to be less than the switching threshold value of 1.35 V, by switching to the second power save mode, the power saving effect can be further enhanced, and the duration until the controller 20 stops can be extended.

### Second Embodiment

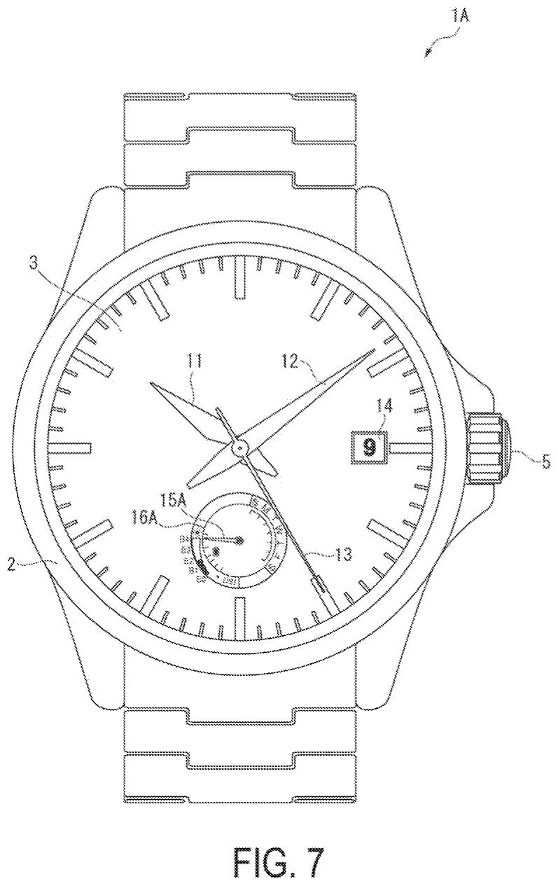

An electronic watch 1A of a second embodiment will be described with reference to FIG. 7. In the electronic watch 1 of the first embodiment, the indicator hand 15 is used only for displaying the power storage amount. In contrast, in the electronic watch 1A of the second embodiment, an indicator hand 15A is used for displaying the power storage amount and also information other than the power storage amount. Note that, in the electronic watch LA, the same components as those of the electronic watch 1 are denoted by the same reference signs, and descriptions thereof will be omitted. Further, since stopping operation of the hour hand 11, the minute hand 12, the seconds hand 13, and the date indicator 14 in the first and second power save modes are the same as those in the first embodiment, the descriptions thereof will be omitted.

The electronic watch 1A is provided with the indicator hand 15A and a scale 16A at a position in the 6 o'clock direction with respect to the plane center position of the dial 3.

As illustrated in FIG. 7, in the scale 16A, characters of “DST” and a symbol of “•” are written from the 6 o'clock direction to the 7 o'clock direction from the rotation axis of the indicator needle 15A. DST (daylight saving time) means summer time. The indicator hand 15A displays a setting of the summer time (DST: summer time ON, •: summer time OFF) by indicating these characters and symbol.

The scales B0 to B4 indicating the power storage amount are displayed from the 7 o'clock direction to the 9 o'clock direction of the scale 16A. Further, when a solar cell is provided as the power generator 22 in the electronic watch 1A, a sun mark indicating that the solar cell is generating power may be displayed on a clockwise direction side of the scale B4.

In a range from the 1 o'clock direction to the 4 o'clock direction of the scale 16A, initial letters of English words indicating a day of the week “S (Sunday)”, “M (Monday)”, “T (Tuesday)”, “W (Wednesday)”, “T (Thursday)”, “F (Friday)”, and “S (Saturday)” are written.

The indicator controller 260 of the electronic watch 1A indicates the day of the week by the indicator hand 15A in the normal time display mode, and indicates the scales B0 to B4 indicating the power storage amount when the operation device 21 is operated. The operation of the operation device 21 may be operation of pulling out the crown 5 to the first stage or the like, or operation of pressing a button when the button is provided.

In the power save mode, the indicator controller 260 indicates the scales B0 to B4 with the indicator hand 15A. That is, when the mode transitions from the normal time display mode to the power save mode, the indicator hand 15A moves from a state of indicating the day of the week to a state of indicating the power storage amount, and continues to indicate the power storage amount during the power save mode. In both the normal time display mode and the power save mode, the indicator controller 260 may display the sun mark with the indicator hand 15A when the power generator 22 is generating power.

### Operations and Effects of Second Embodiment

Since the electronic watch 1A of the second embodiment has the same configuration as that of the first embodiment, the same operations and effects as in the first embodiment can be acquired. In particular, since the indicator hand 15A displays the power storage amount in five stages of B0 to B4 in the power save mode, the user of the electronic watch 1A can understand the decrease in the power storage amount even in the power save mode.

Further, the indicator hand 15A is used not only for indicating the power storage amount but also for indicating the day of the week, presence or absence of the setting of the summer time, and the power generation state. Therefore, information such as the day of the week can be indicated, and the usability of the electronic watch LA can be improved. The information indicated by the indicator hand 15A is not limited to the day of the week, the presence or absence of the setting of the summer time, and the power generation state, and may be information other than these. The information indicated by the indicator hand 15A other than the power storage amount may be set according to a function or the like included in the electronic watch LA.

### Third Embodiment

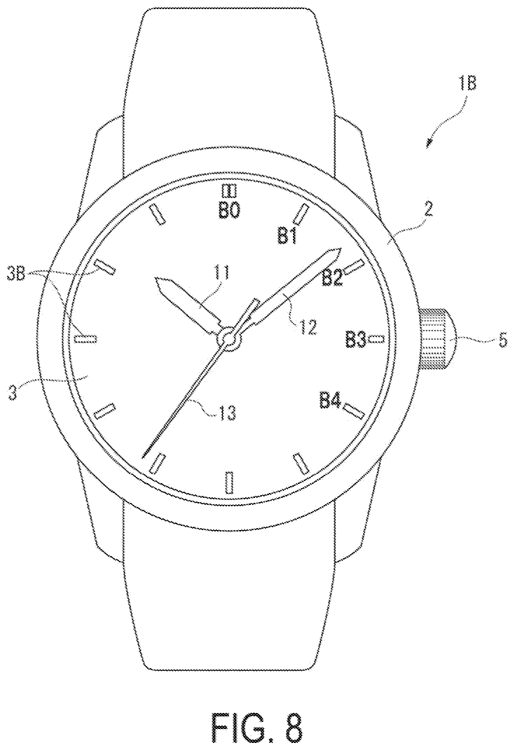

An electronic watch 1B of a third embodiment will be described with reference to FIG. 8. The electronic watch 1B of the third embodiment displays the power storage amount by a hand indicating the time, specifically, by the seconds hand 13 in the power save mode, without including the indicator hand. Therefore, the dial 3 is provided with scales 3B from 12 o'clock to 11 o'clock, and characters B0 to B4 are written inside the scales 3B of 12 o'clock to 4 o'clock, and the scales 3B from 12 o'clock to 4 o'clock are also used as a scale for the power storage amount.

In the electronic watch 1B, in the first power save mode, the hour hand 11 and the minute hand 12 continue to operate and the seconds hand 13 displays the power storage amount, and in the second power save mode, the hour hand 11 and the minute hand 12 stop at the position of 12 o'clock and the seconds hand 13 displays the power storage amount. During each power save mode, the seconds hand 13 stops moving for displaying the time and displays the power storage amount.

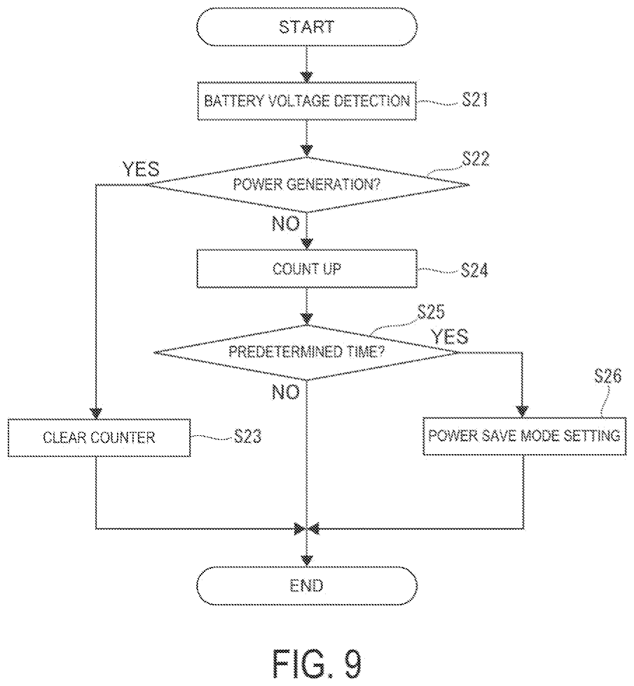

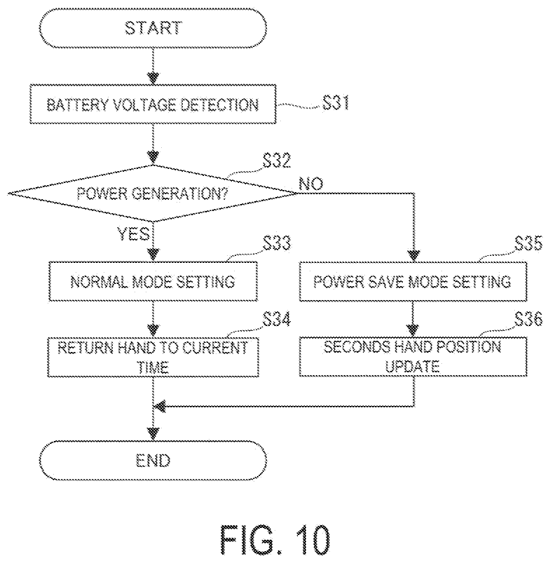

Next, a mode switching process of the electronic watch 1B will be described with reference to flowcharts of FIGS. 9 and 10.

In the normal time display mode, the mode switching controller 230 performs the process illustrated in FIG. 9 every 2 seconds. Similar to the process of FIG. 4 of the first embodiment, in the process of FIG. 9, the battery voltage is detected in a step S21, whether or not it is in the power generation state is determined in a step S22, and when YES is determined in the step S22, the counter is cleared in a step S23 to end the mode switching process.

When NO is determined in the step S22, the mode switching controller 230 counts up the counter in a step S24, and determines whether or not the duration of the non-power generation state has reached a predetermined time in a step S25. Then, when YES is determined in the step S25, the power save mode is set in a step S26 and the mode switching process ends, and when NO is determined in the step S25, the mode switching process then ends.

In the power save mode, the mode switching controller 230 performs the process of FIG. 10 at intervals longer than those in the normal time display mode, such as every minute or every hour. Similar to the process of FIG. 5 of the first embodiment, in the process of FIG. 10, the battery voltage is detected in a step S31, and whether or not it is in the power generation state is determined in a step S32. When YES is determined in the step S32, the mode switching controller 230 sets the normal mode in a step S33, and performs a step S34 in which the hand that has stopped in the power save mode is returned to the position indicating the current time to end the mode switching process.

On the other hand, if NO is determined in the step S32, the mode switching controller 230 sets the power save mode in a step S35, and performs a step S36 to update the position of the seconds hand 13 based on the voltage detected in the step S31 to indicate any of the scales B0 to B4, and ends the mode switching process.

### Operations and Effects of Third Embodiment

In the power save mode, since the electronic watch 1B performs the step S36 of FIG. 10 and indicates any of the scales B0 to B4 by the seconds hand 13 according to the voltage detection result, the power storage amount in the power storage unit 23, that is, the remaining battery level, can be displayed. Therefore, similarly to the first embodiment, the user of the electronic watch 1B can operate the power generation function before the power storage amount decreases to a level at which the controller 20 stops in the power save mode.

Further, since the power storage amount is displayed by the seconds hand 13 and it is not necessary to provide the indicator hand, the number of hands and the number of stepping motors can be reduced, and the electronic watch 1B having a simple design can be provided. Note that in the electronic watch 1B, the power storage amount is displayed by the seconds hand 13. However, in an electronic watch not provided with the seconds hand, the power storage amount may be displayed by the hour hand or the minute hand.

Since the electronic watch 1B displays the power storage amount by the seconds hand 13 in the power save mode, the power saving effect can be increased as compared with the case where the seconds hand 13 is moved to display the time in the power save mode.

In the electronic watch 1B, B0 is set on the scale 3B at the 12 o'clock position. Therefore, the seconds hand 13 indicates the 12 o'clock position when the power storage amount is the lowest. In general, each hand in a watch moves right, that is, clockwise from the 12 o'clock position, so that the number indicated by the hand increases.

For example, in the case of the seconds hand 13, by indicating 0 second at the 12 o'clock position and moving right, the number of indicated seconds also increases as 1, 2 . . . and 59 seconds. Therefore, even when the power storage amount is indicated by a hand such as the seconds hand 13 or the like, by setting B0, which is the lowest level of the power storage amount, at the 12 o'clock position, the user can visually and intuitively recognize that the power storage amount has decreased to B0, which is the lowest level, when the seconds hand 13 indicates the 12 o'clock position. Furthermore, since the scales of B1 to B4 in which the power storage amount sequentially increases are set clockwise from the 12 o'clock position, the user can intuitively understand the level of the power storage amount by checking the position indicated by the seconds hand 13.

### Fourth Embodiment

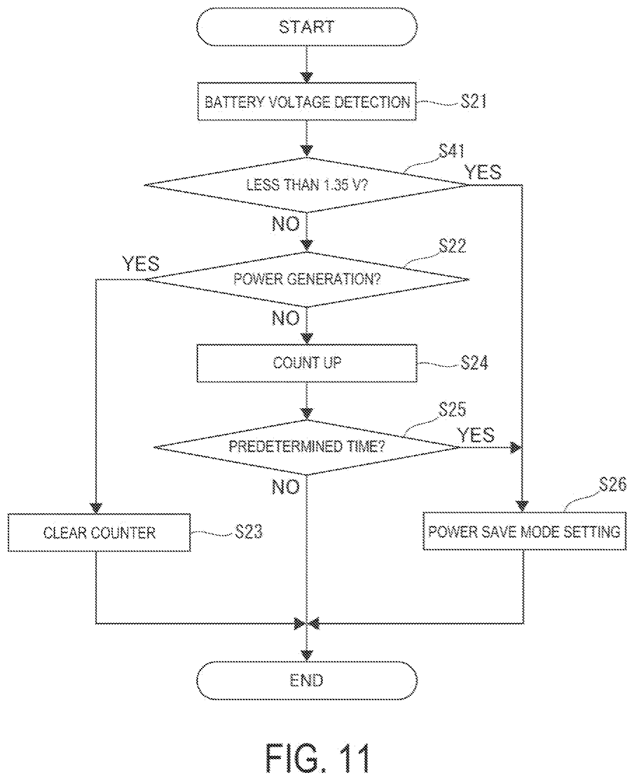

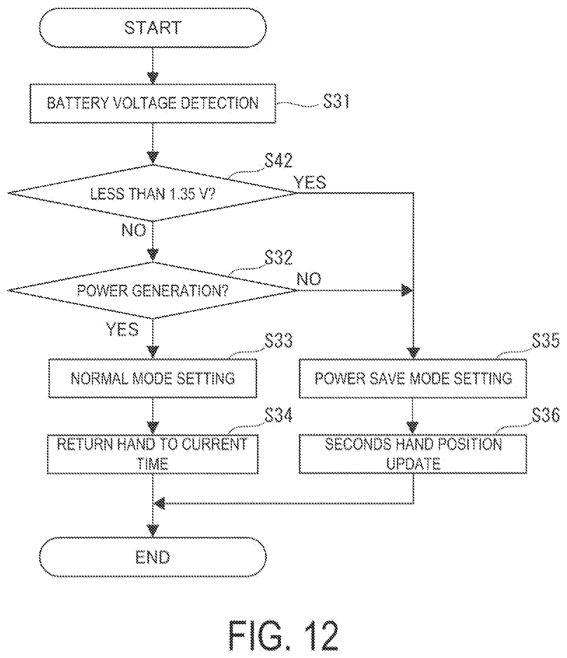

Next, an electronic watch of a fourth embodiment will be described with reference to FIGS. 11 and 12. The fourth embodiment is different from the electronic watch 1B of the third embodiment in apart of the mode switching process in the normal time display mode and the power save mode. Therefore, in FIGS. 11 and 12, the same processes as those in FIGS. 9 and 10 of the third embodiment are denoted by the same reference signs and the descriptions thereof will be omitted.

In the normal time display mode, the mode switching controller 230 performs the process of FIG. 11 every 2 seconds, detects the battery voltage in the step S21 as in the third embodiment, and determines whether or not the detected voltage is less than 1.35 V in a step S41.

When determining NO in the step S41, the mode switching controller 230 performs the steps S22 to S26 as in the third embodiment, and when determining YES in the step S41, the mode switching controller 230 performs the step S26 to end the mode switching process.

In the power save mode, the mode switching controller 230 performs the process of FIG. 12 every minute or every hour, detects the battery voltage in the step S31 and determines whether or not the detected voltage is less than 1.35 V in a step S42.

When determining NO in the step S42, the mode switching controller 230 performs the steps S32 to S36 as in the third embodiment, and when determining YES in the step S42, the mode switching controller 230 performs the steps S35 and S36 to end the mode switching process.

Accordingly, in the fourth embodiment, in the normal time display mode, the mode is switched to the power save mode when the power storage amount, that is, the battery voltage is less than a threshold value of 1.35 V. Further, in the power save mode, when the power storage amount is equal to or greater than 1.35 V, which is a determination value, and the power generation state is detected, the mode is switched to the normal time display mode, and when the power storage amount is less than 1.35 V, which is the determination value, the power save mode is maintained regardless of the detection of the power generation state.

### Operations and Effects of Fourth Embodiment

According to the fourth embodiment, the same operations and effects as those of the third embodiment can be acquired. Further, in the normal time display mode, when the battery voltage is less than the threshold value of 1.35 V in the step S41, the power save mode is set in the step S26 even when the duration of the non-power generation state is less than the predetermined time. Therefore, when the power storage amount decreases, the mode automatically transitions to the power save mode, so that the power can be effectively saved even when the power storage amount decreases because the power cannot be sufficiently generated due to the electronic watch 1B being hidden by the sleeve and the like, and thus the time to maintain the internal timekeeping function can be extended.

Further, since the electronic watch 1B does not include an indicator hand, it is difficult to understand the decrease in the power storage amount in the normal time display mode, but the mode can automatically transition to the power save mode when the battery voltage, that is, the power storage amount is decreased, and the power storage amount can be displayed by the seconds hand 13.

Further, in the power save mode, when the battery voltage is less than 1.35 V, which is the determination value in the step S42, the power save mode is maintained without returning to the normal mode regardless of the presence or absence of power generation, so that sufficient power can be stored and then can return to the normal mode.

### Modification Example

The present disclosure is not limited to the above-described embodiments, and modifications, improvements, and the like within the scope in which the object of the present disclosure can be achieved are included in the present disclosure.

For example, in the embodiment described above, the voltage of the power storage unit 23 is detected and the power storage amount is displayed in multiple stages based on the voltage. However, the power generation amount of the power generator 22, that is, electric charge may be integrated and the power storage amount may be displayed in multiple stages according to the calculated charge amount.

The interval of performing the mode switching process in the normal time display mode and the power save mode is not limited to the example of each of the above-described embodiments. For example, the mode switching process in the normal time display mode is not limited to the interval of 2 seconds, but may be a minute interval, 30 minutes interval, or an hour interval. Similarly, the mode switching process in the power save mode can be appropriately set. In particular, in the power save mode, the power consumption can be further reduced by lengthening the battery voltage detection interval by the voltage detection controller 250, that is, the display update interval of the power storage amount by the indicator hands 15 and 15A and the seconds hand 13. Further, the display update interval of the power storage amount may be different depending on each of the first and second power save modes. Further, the update interval of the indicator hand 15 and the seconds hand 13 for displaying the power storage amount may be varied according to the remaining battery level.

In each of the above embodiments, the mode is transitioned to the power save mode when the non-power generation state continues for a predetermined time. However, the mode may be transitioned to the power save mode when the user manually performs the switching operation, for example, when the crown 5 is pulled out from the zero step position to the first step or second step position. When the user's manual operation transitions to the power save mode, the voltage decrease of the electronic watch that the user does not use for a while can be effectively suppressed.

When the battery voltage drops to the level of the scale B0 in the normal time display mode, a BLD (Battery Low Display) hand movement that warns that the battery voltage has dropped may be performed. The BLD hand movement is a hand movement which indicates that the battery voltage has dropped, and the seconds hand 13 is moved at intervals of 2 seconds or more, for example, 2 second intervals or 5 second intervals. In the BLD hand movement, the minute hand 11 and the hour hand 12 are moved as usual. The BLD hand movement is also referred to as a battery low display, a battery life indicator, or the like.

In the third and fourth embodiments, the power storage amount is displayed by the seconds hand 13. However, three hands of the hour hand 11, the minute hand 12, and the seconds hand 13 may be driven, and the scales B0 to B4 may be simultaneously indicated by the three hands. When the scales B0 to B4 are indicated by the three hands in this way, the hand movement becomes different from the time display, so that the user can easily understand that the power storage amount is indicated. Note that the scales B0 to B4 may be indicated by two of the three hands, and the scales B0 to B4 may be indicated by the two hands of the hour and minute hands in an electronic watch including only two hands of the hour and minute hands.

Further, in the embodiment described above, the power storage amount is displayed by the indicator hands 15 and 15A and the seconds hand 13. However, the power storage amount may be displayed by other than the hands. For example, the characters B0 to B4 may be written on the dial 3 and the dial 3 may be moved to display the power storage amount.

In each of the embodiments described above, the power storage amount is displayed in five stages of B0 to B4, but is not limited to five stages, and may be displayed in three stages or the like, and may be displayed in a plurality of stages. For example, in the first power save mode, the power storage amount may be displayed in two stages, and in the second power save mode, the power storage amount may be displayed in one stage.

In each of the embodiments described above, two power save modes of the first and second are set as the power save mode. However, only one power save mode may be set. Further, in the first power save mode, only the seconds hand is stopped. However, only other hands may be stopped, or the plurality of hands may be stopped.

The threshold value for switching from the normal time display mode to the power save mode, and the determination value for maintaining the power save mode regardless of the power generation state in the power save mode in the fourth embodiment, and the switching threshold value for switching the first and second power save mode in each embodiment, are set to 1.35 V, which is the same value. However, each may be set to a different value.

In each of the embodiments described above, the hour hand 11, the minute hand 12, and the seconds hand 13 are configured to move independently. However, the hour hand 11 and the minute hand 12 may be moved in conjunction with each other. In this case, since the motor driver, the stepping motor, and the train wheel for moving the hour hand 11 and the minute hand 12 can be used together, the size and cost of the electronic watch can be reduced.

Further, when the indicator hands 15 and 15A are provided, the hour hand 11, the minute hand 12, and the seconds hand 13 may be moved in conjunction with each other.

Further, the hour hand 11 may be moved independently, and the minute hand 12 and the seconds hand 13 may be moved in conjunction with each other. In this case, the hour hand 11 may be used to display the power storage amount, or the indicator hands 15 and 15A may be provided to display the power storage amount.

### SUMMARY OF PRESENT DISCLOSURE

An electronic watch of the present disclosure includes a plurality of hands configured to display time, a power generator, a power storage unit configured to store power generated by the power generator, an indicator hand configured to display a power storage amount in the power storage unit in a plurality of stages, a controller configured to perform control switching between a normal time display mode in which time is displayed by the hand and a power save mode in which at least one of the hands is stopped, and the controller detects the power storage amount and updates display of the power storage amount by the indicator hand during the power save mode.

According to the electronic watch of the present disclosure, the power storage amount of the power storage unit is displayed in a plurality of stages by the indicator hand during the power save mode. Therefore, the user of the electronic watch can understand the decrease in the power storage amount even in the power save mode, and can operate the power generator to increase the power storage amount before the power storage amount decreases to a level at which the controller stops. Thus, a user having a plurality of electronic watches can select the electronic watch with a low power storage amount from among the plurality of electronic watches that have transitioned to the power save mode to generate power preferentially, thereby preventing the controller from stopping due to a voltage drop.

In the electronic watch of the present disclosure, the controller may be configured to display other information different from the power storage amount by the indicator hand during the normal time display mode, and to cause the indicator hand to switch from display of the other information to the display of the power storage amount after switching from the normal time display mode to the power save mode.

According to the electronic watch of the present disclosure, during the normal time display mode, since the indicator hand display other information different from the power storage amount such as the day of the week, the presence or absence of the summer time setting, and the power generation state, usability of the electronic watch can be improved. Further, since the indicator hand displays the power storage amount during the power save mode, the decrease in the power storage amount can be easily understood and power can be generated in the power generator to prevent the decrease in the power storage amount.

An electronic watch of the present disclosure includes a plurality of hands configured to display time, a power generator, a power storage unit configured to store power generated by the power generator, and a controller configured to perform control switching between a normal time display mode in which time is displayed by the hand and a power save mode with less power consumption than the normal time display mode, and when switched from the normal time display mode to the power save mode, the controller switches to display a power storage amount in the power storage unit in a plurality of stages by one hand of the hands.

According to the electronic watch of the present disclosure, the power storage amount of the power storage unit is displayed in a plurality of stages by one hand during the power save mode. Therefore, the user of the electronic watch can understand the decrease in the power storage amount in the power save mode, and can operate the power generator to increase the power storage amount before the power storage amount decreases to a level at which the controller stops. Thus, a user having a plurality of electronic watches can preferentially select the electronic watch with a low power storage amount from among the plurality of electronic watches that have transitioned to the power save mode, thereby preventing the controller from stopping due to a voltage drop.

Further, since the power storage amount does not vary significantly in a short time, the detection interval of the power storage amount, that is, the movement interval of the hand that displays the power storage amount can be made longer than the movement interval of the hand in the normal time display mode. Therefore, in the hand, power consumption can be reduced when displaying the power storage amount than when displaying the time, so that the power saving effect in the power save mode can be increased.

In the electronic watch of the present disclosure, the one hand of the hands may be a seconds hand.

The movement interval of the seconds hand is shorter than those of the hour hand and minute hand, so the seconds hand consumes more power. When the power storage amount is displayed by the seconds hand in the power save mode, the seconds hand does not move to display the time, so that the power saving effect can be increased.

In the electronic watch of the present disclosure, when displaying the power storage amount at the lowest stage of the plurality of stages, the one hand of the hands may indicate a position of 12 o'clock.

According to the electronic watch of the present disclosure, since the hand that displays the power storage amount indicates the lowest stage of the power storage amount by indicating the 12 o'clock position, the visibility can be improved and the user can easily confirm that the power storage amount is decreasing.

In the electronic watch of the present disclosure, a detection interval of the power storage amount during the power save mode may be longer than a detection interval of the power storage amount during the normal time display mode.

According to the electronic watch of the present disclosure, the power saving effect during the power save mode can be further increased.

In the electronic watch of the present disclosure, the controller may switch from the normal time display mode to the power save mode when a duration of a non-power generation state in which power generation is not performed by the power generator is equal to or greater than a predetermined time.

According to the electronic watch of the present disclosure, when the non-power generation state continues for a predetermined time such as 3 hours or 24 hours, the mode is automatically switched to the power save mode, so that in the electronic watch or the like stored at home or the like, power can be effectively saved.

In the electronic watch of the present disclosure, the controller may switch to the power save mode when the power storage amount is less than a threshold value.

According to the electronic watch of the present disclosure, when the power storage amount decreases to be less than the threshold value, the mode automatically switches to the power save mode, so that the power can be effectively saved even when the power storage amount decreases in the state where the power cannot be sufficiently generated due to the electronic watch being hidden by the sleeve and the like.

The electronic watch of the present disclosure may include an operation device, and when the controller detects that switching operation has been performed by the operation device, the controller may switch to the power save mode.

According to the electronic watch of the present disclosure, since the electronic watch can be switched to the power save mode by the user's operation, the electronic watch to be stored at home can be set to the power save mode by the user's intention and power can be saved effectively.

In the electronic watch of the present disclosure, when the power storage amount is equal to or greater than a determination value during the power save mode, the controller may be configured to switch to the normal time display mode when a power generation state in which the power generator generates power is detected, and when the power storage amount is less than the determination value during the power save mode, the controller may be configured to maintain the power save mode even when the power generation state is detected.

According to the electronic watch of the present disclosure, when the power storage amount is less than the determination value, the power save mode is maintained even when the power generation state is detected, and when the power storage amount becomes equal to or greater than the determination value and the power generation state is detected, the mode is switched to the normal time display mode. Therefore, the power save mode can be maintained as long as the power storage amount is not greater than the determination value. Therefore, it is possible to prevent the switching to the normal time display mode in a state where the power storage amount is low and thus to prevent the controller from stopping due to a decrease in the power storage amount in a short time.

In the electronic watch of the present disclosure, the controller may be configured to perform control switching between, as the power save mode, a first power save mode and a second power save mode with less power consumption than the first power save mode, when switching from the normal time display mode to the power save mode, the controller may switch to control in the first power save mode when the power storage amount is equal to or greater than a switching threshold value, and may switch to control in the second power save mode when the power storage amount is less than the switching threshold value, and during the control in the first power save mode, the controller may switch to control in the second power save mode when the power storage amount decreases to be less than the switching threshold value.

The first power save mode and the second power save mode that consumes less power are included as the power save mode. Therefore, when the power storage amount decreases to be less than the switching threshold value, by switching to the second power save mode, the power saving effect can be further enhanced, and the duration until the controller stops can be extended.

A method for controlling an electronic watch according to the present disclosure, the electronic watch including a plurality of hands configured to display time, a power generator, a power storage unit configured to store power generated by the power generator, and an indicator hand configured to display a power storage amount in the power storage unit, the method including, when a switching condition is satisfied, switching to a power save mode in which at least one of the hands is stopped, and while performing the power save mode, detecting the power storage amount in the power storage unit, and causing the indicator hand to display the power storage amount in a plurality of stages.

According to the method for controlling the electronic watch of the present disclosure, the power storage amount in the power storage unit is displayed in a plurality of stages by the indicator hand during the power save mode. Therefore, the user of the electronic watch can understand the decrease in the power storage amount even in the power save mode, and can operate the power generator to increase the power storage amount before the power storage amount decreases to a level at which the controller stops. Thus, a user having a plurality of electronic watches can select the electronic watch with a low power storage amount from among the plurality of electronic watches that have transitioned to the power save mode to generate power preferentially, thereby preventing the controller from stopping due to a voltage drop.

A method for controlling an electronic watch according to the present disclosure, the electronic watch including a plurality of hands configured to display time, a power generator, and a power storage unit configured to store power generated by the power generator, the method including, when a switching condition is satisfied while performing a normal time display mode in which time is displayed by the hands, switching to a power save mode with less power consumption than the normal time display mode, and while performing the power save mode, during performance of the power save mode, detecting the power storage amount in the power storage unit, and displaying the power storage amount in a plurality of stages by one hand of the hands.

According to the method for controlling the electronic watch of the present disclosure, the power storage amount in the power storage unit is displayed in a plurality of stages by one hand during the power save mode. Therefore, the user of the electronic watch can understand the decrease in the power storage amount in the power save mode, and can operate the power generator to increase the power storage amount before the power storage amount decreases to a level at which the controller stops. Thus, a user having a plurality of electronic watches can preferentially select the electronic watch with a low power storage amount from among the plurality of electronic watches that have transitioned to the power save mode, thereby preventing the controller from stopping due to a voltage drop.

Further, since the power storage amount does not vary significantly in a short time, the detection interval of the power storage amount, that is, the movement interval of the hand that displays the power storage amount can be made longer than the movement interval of the hand in the normal time display mode. Therefore, in the hand, power consumption can be reduced when displaying the power storage amount than when displaying the time, so that the power saving effect in the power save mode can be increased.

What is claimed is:

1. An electronic watch comprising:
a plurality of hands configured to display time,
a power generator,
a power storage unit configured to store power generated by the power generator,
an indicator hand configured to display a power storage amount in the power storage unit in a plurality of stages,
a controller configured to perform control switching between a normal time display mode in which time is displayed by the hand and a power save mode in which at least one of the hands is stopped, wherein
the controller, during the power save mode, causes the indicator hand to display the power storage amount, and during the power save mode, detects the power storage amount and updates display of the power storage amount by the indicator hand.

2. The electronic watch according to claim 1, wherein
the controller is configured to display other information different from the power storage amount by the indicator hand during the normal time display mode, and
to cause the indicator hand to switch from display of the other information to the display of the power storage amount after switching from the normal time display mode to the power save mode.

3. The electronic watch according claim 1, wherein
the controller detects the power storage amount during the normal time display mode, and
a detection interval of the power storage amount during the power save mode is longer than a detection interval of the power storage amount during the normal time display mode.

4. The electronic watch according claim 1, wherein
the controller switches from the normal time display mode to the power save mode when a duration of a non-power generation state in which power generation is not performed by the power generator is equal to or longer than a predetermined time.

5. The electronic watch according to claim 1, wherein
the controller switches from the normal time display mode to the power save mode when the power storage amount is less than a threshold value.

6. The electronic watch according to claim 1 comprising:
an operation device, wherein
when the controller detects that switching operation was performed by the operation device, the controller switches from the normal time display mode to the power save mode.

7. The electronic watch according to claim 1, wherein
the controller is configured to, when the power storage amount is equal to or greater than a determination value during the power save mode, switch to the normal time display mode when a power generation state in which the power generator generates power is detected, and
the controller is configured to, when the power storage amount is less than the determination value during the power save mode, maintain the power save mode even when the power generation state is detected.

8. The electronic watch according to claim 1, wherein
the controller is configured to perform control switching between, as the power save mode, a first power save mode and a second power save mode with less power consumption than the first power save mode,
when switching from the normal time display mode to the power save mode, the controller switches to control in the first power save mode when the power storage amount is equal to or greater than a switching threshold value, and switches to control in the second power save mode when the power storage amount is less than the switching threshold value, and
the controller switches to control in the second power save mode when the power storage amount decreases to be less than the switching threshold value during the control in the first power save mode.

9. An electronic watch comprising:
a plurality of hands configured to display time,
a power generator,
a power storage unit configured to store power generated by the power generator, and
a controller configured to perform control switching between a normal time display mode in which time is displayed by the hand and a power save mode with less power consumption than the normal time display mode, wherein
after switching from the normal time display mode to the power save mode, the controller displays a power storage amount in the power storage unit in a plurality of stages by one hand of the hands, and during the power save mode, detects the power storage amount and updates display of the power storage amount by the one hand.

10. The electronic watch according to claim 9, wherein
the one hand of the hands is a seconds hand.

11. The electronic watch according claim 9, wherein
when displaying the power storage amount at the lowest stage of the plurality of stages, the one hand of the hands indicates a position of 12 o'clock.

12. The electronic watch according claim 9, wherein
the controller detects the power storage amount during the normal time display mode, and
a detection interval of the power storage amount during the power save mode is longer than a detection interval of the power storage amount during the normal time display mode.

13. The electronic watch according claim 9, wherein
the controller switches from the normal time display mode to the power save mode when a duration of a non-power generation state in which power generation is not performed by the power generator is equal to or longer than a predetermined time.

14. The electronic watch according to claim 9, wherein
the controller switches from the normal time display mode to the power save mode when the power storage amount is less than a threshold value.

15. The electronic watch according to claim 9 comprising:
an operation device, wherein
when the controller detects that switching operation was performed by the operation device, the controller switches from the normal time display mode to the power save mode.

16. The electronic watch according to claim 9, wherein
the controller is configured to, when the power storage amount is equal to or greater than a determination value during the power save mode, switch to the normal time display mode when a power generation state in which the power generator generates power is detected, and
the controller is configured to, when the power storage amount is less than the determination value during the power save mode, maintain the power save mode even when the power generation state is detected.

17. The electronic watch according to claim 9, wherein
the controller is configured to perform control switching between, as the power save mode, a first power save mode and a second power save mode with less power consumption than the first power save mode,
when switching from the normal time display mode to the power save mode, the controller switches to control in the first power save mode when the power storage amount is equal to or greater than a switching threshold value, and switches to control in the second power save mode when the power storage amount is less than the switching threshold value, and
the controller switches to control in the second power save mode when the power storage amount decreases to be less than the switching threshold value during the control in the first power save mode.

18. A method for controlling an electronic watch, comprising:
determining whether a switching condition is satisfied while performing a normal time display mode in which time is displayed by hands,
switching to a power save mode in which at least one of the hands is stopped when the switching condition is satisfied, and
while performing the power save mode,
causing an indicator hand to display a power storage amount in a power storage unit in a plurality of stages,
detecting the power storage amount in the power storage unit, and
updating display of the power storage amount by the indicator hand based on the detected power storage amount.
